(19) United States
(12) Patent Application Publication
(10) Pub. No.: US 2005/0082945 A1
(43) Pub. Date: Apr. 21, 2005

(54) Load-adjustable surface acoustic wave actuator arrangement

(75) Inventors: Ta-Hsin Chou, Kaohsiung City (TW); Yi-Ming Chu, Lujhu Township (TW); Wei-Han Wang, Sindian City (TW); Cheng-Hua Wu, Yongjing Township (TW)

Correspondence Address: BROWDY AND NEIMARK, P.L.L.C.;624 NINTH STREET, NW, SUITE 300, WASHINGTON, DC, 20001-5303, US

(73) Assignee: Industrial Technology Research Institute, Hsinchu Hsien (TW)

(21) Appl. No.: 10/686,595

(22) Filed: Oct. 17, 2003

(51) Int. Cl. H01L 41/04

(52) U.S. Cl. 310/328

(57) ABSTRACT

A load-adjustable SAW (Surface Acoustic Wave) actuator arrangement includes a platform having two sliding bearings symmetrically disposed at two sides; a SAW actuator disposed in the platform between the sliding bearings for producing a surface acoustic wave at the top surface thereof, a slider disposed inside the platform and movable by the SAW actuator along the sliding bearings, and a support structure. The slider has a pressure bearing structure disposed in contact with the top surface of the SAW actuator and two positioning portions respectively supported on the sliding bearings. The support structure applies a predetermined force to the slider subject to the load carried on the slider, keeping the contact pressure between the slider and the SAW actuator about a constant value.

### BACKGROUND OF THE INVENTION

1. Field of the Invention

The present invention relates to surface acoustic wave actuators and, more particularly, to a load-adjustable surface acoustic wave actuator.

2. Description of the Related Art

Surface acoustic wave (SAW) is a wave of physical phenomena that is transferred along the surface of a semiinfinite elastomer. When making interdigital transducers (IDT) at the surface of a piezoelectric transistor and then inputting a voltage to the interdigital transducers, the piezoelectric transistor will be caused to produce a surface acoustic wave at the surface due to converse piezoelectric effect. This technology is intensively used in electronic communication industry to filter or process signal.

Because surface acoustic wave has a low amplitude and high resonant frequency, it is found to be practical for use in a nanometer platform to move an object. However, because surface acoustic wave actuation technology is to use the surface of a piezoelectric transistor to produce surface acoustic wave for controlling the positioning of a slider in a platform, the surface acoustic wave actuation effect has a great concern with the contact pressure between the slider and the surface of the piezoelectric transistor, i.e., the load at the slider affects the contact pressure between the slider and the piezoelectric transistor, and the contact pressure between the slider and the piezoelectric transistor affects the surface acoustic wave actuation effect. In laboratories, gravity, magnetic force or spring force is used to produce the desired contact pressure between the slider and the piezoelectric transistor. However these contact pressure producing methods cannot compensate the variation of load in the platform. The driving performance of the platform is affected when the slider carrying a load of excessively high or low weight. FIG. 1 is a pressure-displacement curve explaining the relation between the displacement per each 3 seconds of sliders of different sizes and the contact pressure. Within a certain range, the greater the contact pressure between the slider and the SAW actuator is, the faster the slider will be. However, when the contact pressure between the slider and the SAW actuator surpassed the range (excessively high), the speed of the slider becomes slow. Therefore, properly adjust the contact pressure between the slider and the SAW actuator improves the driving performance of the platform.

Therefore, it is importance to maintain the driving performance of the platform by adjusting the forward pressure (contact pressure) between the slider and the SAW actuator (piezoelectric transistor) to a constant value subject to the weight of the load carried on the slider. Normally, there are three adjustment methods, one is to change the weight at the slider, the second is to change the magnetic attraction between a permanent magnet and an iron plate, and the third is to change the amount of deformation of the spring. However, these methods are not practical in application. If the load is unknown, the adjustment control of the contact pressure between the slider and the SAW actuator becomes not workable.

### SUMMARY OF THE INVENTION

It is therefore the main object of the present invention to provide a load-adjustable SAW actuator arrangement, which keeps the contact pressure between the slider and the SAW actuator within a constant value, ensuring satisfactory driving effect of the SAW actuator.

It is another object of the present invention to provide a load-adjustable SAW actuator arrangement, which keeps the slider moving in a predetermined direction.

To achieve these objects of the present invention, the load-adjustable SAW (Surface Acoustic Wave) actuator arrangement comprises a platform having two sliding bearings symmetrically disposed at two sides thereof; a SAW (Surface Acoustic Wave) actuator disposed in the platform between the sliding bearings for producing a surface acoustic wave at a top surface thereof; a slider disposed inside the platform and movable by the SAW actuator along the sliding bearings, and a support structure. The slider has a pressure bearing structure disposed in contact with the top surface of the SAW actuator, and two positioning portions respectively supported on the sliding bearings. The support structure applies a predetermined force to the slider subject to the load carried on the slider, keeping the contact pressure between the slider and the SAW actuator about a constant value.

### BRIEF DESCRIPTION OF THE DRAWINGS

FIG. 1 is a pressure-displacement curve explaining the relation between the displacement of the slider and the contact pressure between the slider and the SAW actuator.

FIG. 2 shows SAW (surface acoustic wave) actuator arrangement according to the present invention.

FIG. 3 is a sectional view of FIG. 2.

FIG. 4 is a schematic drawing showing downward pressure, upward pressure, and lateral pressure applied to the slider according to the present invention.

FIG. 5 is a schematic drawing showing a Hertz contact theory model and its calculation of contact pressure.

FIG. 6 is a schematic drawing showing downward pressure, upward pressure, and lateral pressure applied to the slider according to an alternate form of the present invention.

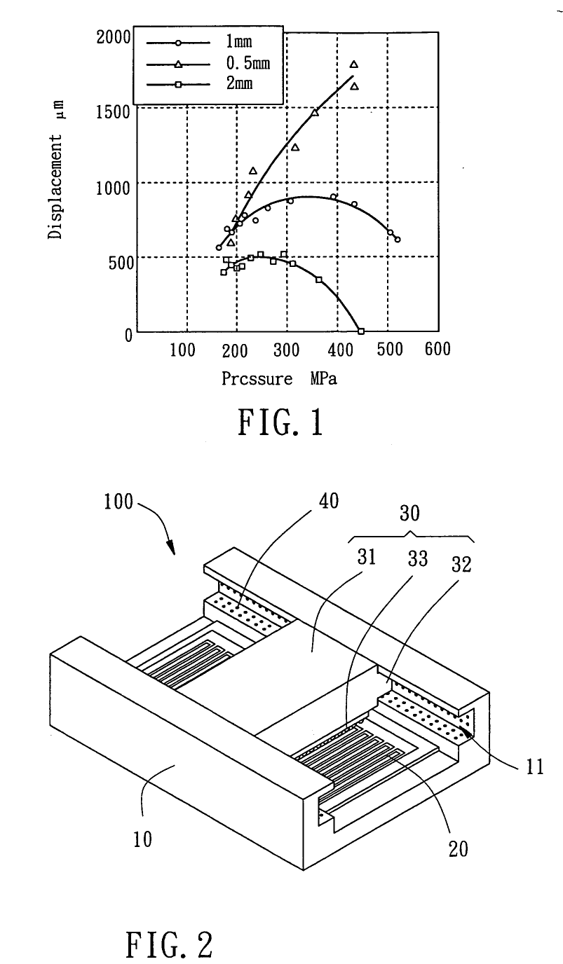

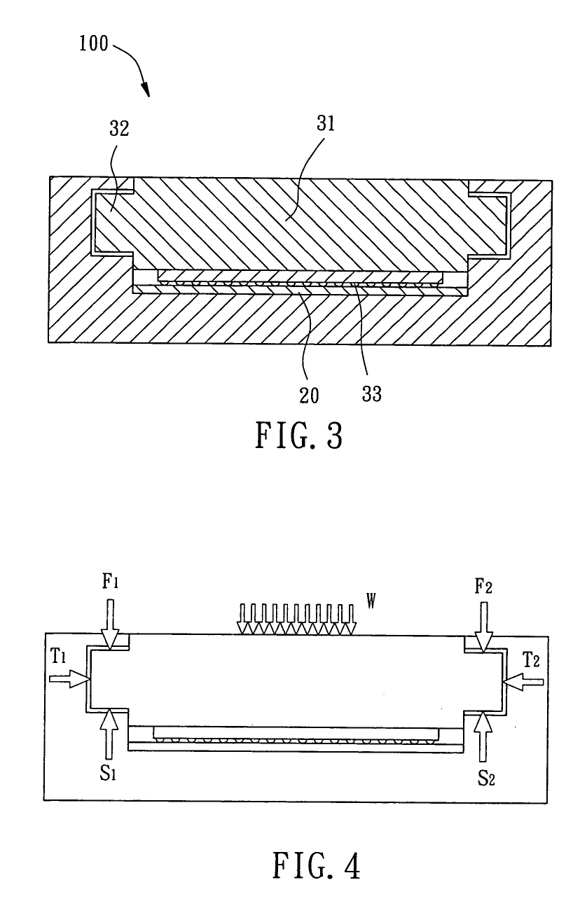

### DETAILED DESCRIPTION OF THE INVENTION

Referring to FIGS. From 2 to 4, a SAW (surface acoustic wave) actuator arrangement 100 in accordance with the present invention is shown comprised of a platform 10, a SAW actuator 20, a slider 30, and a support structure 40.

The platform 10 has a top-open receiving area adapted to accommodate the slider 30, and two sliding bearings 11 symmetrically disposed at two sides inside the top-open receiving area 30. According to this embodiment, the sliding bearings 11 are longitudinal grooves.

The SAW actuator 20 is made of piezoelectric material (transistor) and arranged at the bottom side in the top-open receiving area of the platform 10, having a plurality of interdigital electrodes disposed at the top surface (not shown) for input of voltage to cause the piezoelectric material to produce a converse piezoelectric effect and to further generate a surface acoustic wave of low amplitude and high resonant frequency at the top surface of the SAW actuator 20.

The slider 30 comprises a slider body 31, two positioning portions 32, and a pressure bearing structure 33. The slider body 31 is shaped like a block. The positioning portions 32 are respectively outwardly extended from two opposite sides of the slider body 31. The pressure bearing structure 33 is comprised of a plurality of balls aligned in lines at the bottom side of the slider body 31. The slider body 31 is suspended in the top-open receiving area inside the platform 10, keeping the positioning portions 32 respectively suspended in the sliding bearings 11 and spaced from the sidewalls (top, bottom and lateral sidewalls) of the sliding bearings 11 at a distance. The pressure bearing structure 33 is disposed in contact with the top surface of the SAW actuator 20. The slider body 31 carries a pressure sensor (not shown) at the top side, which converts the variation of load at the slider 30 into a corresponding value and then transmits such value to a processor (not shown). Because the pressure sensor and the processor are of the known parts, no further detailed description in this regard is necessary.

The support structure 40 is controlled to work by the aforesaid processor. According to this embodiment, the support structure 40 is comprised of three gas suppliers each having an independent gas source. The first gas supplier has a plurality of gas nozzles arranged in lines at the bottom sidewalls of the sliding bearings 11 and disposed in comnunication with the sliding bearings 11. The second gas supplier has a plurality of gas nozzles arranged in lines at the top sidewalls of the sliding bearings 11 and disposed in communication with the sliding bearings 11. The third gas supplier has a plurality of gas nozzles arranged in lines at the lateral sidewalls of the sliding bearings 11 and disposed in communication with the sliding bearings 11. Therefore, the gas suppliers of the support structure 40 give an air pressure to the sliding bearings 11 from different directions. The operation of the SAW actuator arrangement 100 is outlined hereinafter.

When moving an object horizontally by the slider 30 to a predetermined location, put the object on the slider 30 at first. At this time, the gravity weight of the object is added to the slider 30, thereby causing the slider 30 to produce a downwardly extended forward pressure W, which causes the contact pressure between the pressure bearing structure 33 of the slider 30 and the SAW actuator 20 to be changed (increased). Therefore, the pressure sensor at the slider 30 transmits the added pressure value of the object to the processor, causing the processor to drive the first, second, and third gas suppliers of the support structure 40 to provide gas to the gas nozzles at the top, bottom and lateral sidewalls of the sliding bearings 11. During supply of gas to the sliding bearings 11, the top sides of the positioning portions 32 of the slider 30 receive downward pressure F1, F2 from the gas provided by the second gas supplier of the support structure 40, and the bottom sides of the positioning portions 32 of the slider 30 receive upward supporting force S1, S2 from the gas provided by the first gas supplier of the support structure 40. The volume of gas supplied by the first gas supplier is greater than the volume of gas supplied by the second gas supplier, therefore the bottom sides of the positioning portions 32 of the slider 30 receive much volume of gas, and the buoyancy (upward supporting force) S1, S2 lifts the slider 30 slightly (see FIG. 4), keeping the contact pressure between the slider 30 and the SAW actuator 20 maintained in a constant value P (such constant value is obtained by means of experimentation and stored in the processor; under the contact pressure of such constant value, the slider 30 is moved at a constant speed). This constant value P is obtained subject to the equation of: P=W+(F1+F2)−(S1+S2). Therefore, when keeping the contact pressure between the slider 30 and the SAW actuator 20 at such constant value P, the SAW actuator 20 can move the slider 30 and the loaded object to a predetermined position at a constant speed by means of a surface acoustic wave.

Further, if the pressure contact is under the constant value P due to a relatively lighter weight of the object carried on the slider 30, the pressure sensor at the slider 30 transmits the pressure value of the load at the slider 30 to the processor, causing the processor to drive the second gas supplier of the support structure 40 to increase the supply of gas over the supply volume of gas from the first gas supplier, i.e., to increase the downward pressure F1, F2 to the top sides of the positioning portions 32 of the slider 30 (see FIG. 4). Therefore, the downwardly extended forward pressure to the slider 30 is relatively increased to adjust the contact pressure between the slider and the SAW actuator 20 upward to the constant value P, meeting the equation of P=W+(F1+F2)−(S1+S2), for enabling the SAW actuator 20 to move the slider 30 at a constant speed.

During horizontal displacement of the slider 30, the third gas supplier of the support structure 40 provides a lateral gas pressure T1, T2, as shown in FIG. 4, keeping the slider 30 in direction.

As indicated above, the support structure of the load-adjustable SAW actuator arrangement of the present invention automatically adjust the upward supporting force or downward pressure to the slider subject to the load at the slider, keeping the contact pressure between the slider and the SAW actuator within a constant value, so that the slider can be moved at a constant speed. This arrangement presents damage to the SAW actuator due to excessive high pressure at the slider, or unstable displacement of the slider due to excessive low (insufficient) pressure of the load at the slider. The support structure can also provide a lateral pressure, keeping displacement of the slider in a constant direction.

According to this embodiment, the pressure bearing structure 33 is comprised of a plurality of balls. Because the amplitude of the surface acoustic wave is as smaller as a number of nanometers, the contact conditions between the SAW actuator and the slider are important. For example, the surface roughness, cleanliness and contact pressure of the SAW actuator are important contact conditions that determine the performance of the SAW actuator. More particularly, the contact pressure between the slider and the SAW actuator must be great enough. Because the SAW actuator oscillates at a frequency of several MHz, excessively low contact pressure between the slider and the SAW actuator causes squeezing of the air film between the slider and the SAW actuator, resulting in unstable contact between the slider and the SAW actuator and low mobility of the slider by the SAW actuator. Ball contact between the slider and the SAW actuator eliminates the aforesaid problems.

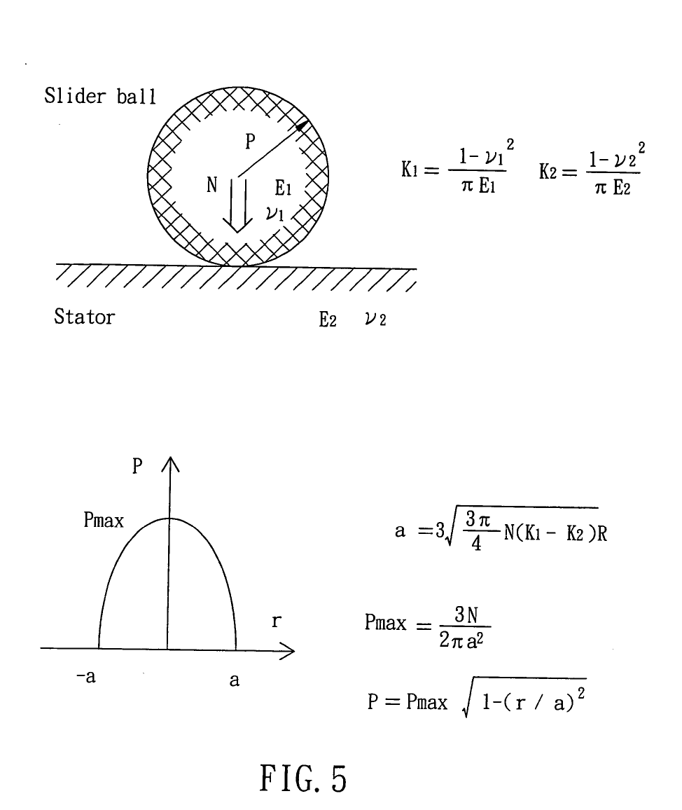

FIG. 5 illustrates a model of Hertz theory in which E1 and E2 are modulus of elasticity of the slider and the SAW actuator; ν1 and ν2 are Possion's Ratio of the slider and the SAW actuator; N is the forward pressure between the slider and the SAW actuator; R is the radius of the slider. According to Hert's contact theory, the maximum contact pressure between the slider and the SAW actuator is Pmax. Therefore, the contact design between the slider and the SAW actuator determines the performance of the driving operation. This explains the ball contact between the slider and the SAW actuator is the best design.

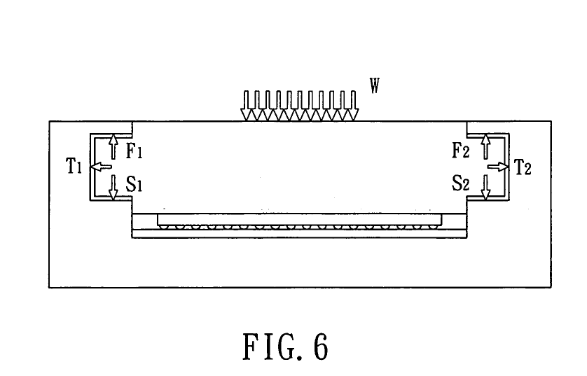

As indicated above, the support structure is disposed at the sliding bearings inside the platform. Alternatively, the support structure can also be provided at the slider. As shown in FIG. 6, the gas nozzles of the gas suppliers of the support structure are respectively disposed at the top, bottom, and lateral sidewalls of the slider. When the slider carrying a relatively heavier load and the contact pressure between the slider and the SAW actuator surpassed the constant value, the support structure will be controlled by the processor to provide more gas to the gas nozzles at the bottom sidewall of the slider to relatively increase upward supporting force S1, S2, adjusting the contact pressure between the slider and the SAW actuator to the constant value.

When the slider carrying a relatively lighter load and the contact pressure between the slider and the SAW actuator dropped below the constant value, the support structure will be controlled by the processor to provide more gas to the gas nozzles at the top sidewall of the slider to relatively increase downward pressure F1, F2, adjusting the contact pressure between the slider and the SAW actuator to the constant value. The support structure is also controlled by the processor to provide lateral (gas) pressure T1, 2, keeping the slider in direction.

According to the aforesaid embodiment, the support structure controls the contact pressure between the slider and the SAW actuator by means of air floating. Actually, the support structure can be a hydraulic or magnetic floating design that provides an adjustable supporting force to keep the contact pressure between the slider and the SAW actuator stable, enabling the slider to be moved at a constant speed when carrying different loads.

The operation principle of a hydraulic or magnetic floating type support structure is substantially similar to the aforesaid air pressure type support structure. When a hydraulic design of support structure is adopted, the support structure is made having three independent hydraulic devices. The first hydraulic device has a plurality of output nozzles arranged in lines at the bottom sidewalls of the sliding bearings and disposed in communication with the sliding bearings; the second hydraulic device has a plurality of output nozzles arranged in lines at the top sidewalls of the sliding bearings and disposed in communication with the sliding bearings; the third hydraulic device has a plurality of output nozzles arranged in lines at the lateral sidewalls of the sliding bearings and disposed in communication with the sliding bearings. The first hydraulic device can be controlled to provide an upward supporting force surpassed the downward pressure from the second hydraulic device, or the second hydraulic device can be controlled to provide a downward pressure surpassed the upward supporting force from the first hydraulic device, keeping the contact pressure between the slider and the SAW actuator within the constant value. Further, the third hydraulic device provides a suitable lateral pressure to keep the displacement of the slider in direction. Alternatively the three hydraulic devices of the support structure can be disposed at the top, bottom, and lateral sidewalls of the slider, achieving the same effect.

Further, when a magnetic floating design of support structure is adopted, the support structure is made having three independent electromagnetic devices. The first electromagnetic device is disposed at the bottom sidewalls of the sliding bearings and the corresponding side of the slider; the second electromagnetic device is disposed at the top sidewalls of the sliding bearings and the corresponding side of the slider; the third electromagnetic device is disposed at the lateral sidewalls of the sliding bearings and the corresponding sides of the slider. Upon connection of a predetermined electric current to the first electromagnetic device and a predetermined electric current to the second electromagnetic device, the first electromagnetic device provides an upward floating supporting force to the slider, and the second electromagnetic device provides a downward magnetic pressure to the slider, keeping the contact pressure between the slider and the SAW actuator within the constant value. At the same time, the third electromagnetic device provides a suitable lateral pressure to the slider, keeping the displacement of the slider in direction. According to the aforesaid arrangement, magnetic floating is achieved by means of magnetic repulsion between the slider and the sliding bearings. Alternatively, magnetic floating can be achieved by means of magnetic attraction between the slider and the sliding bearings.

1. A load-adjustable surface acoustic wave actuator arrangement comprising:
a platform having two sliding bearings symmetrically disposed at two sides;
a surface acoustic wave actuator disposed in said platform between said sliding bearings for producing a surface acoustic wave at a top surface thereof;
a slider disposed inside said platform and movable by said surface acoustic wave actuator along said sliding bearings, said slider having a pressure bearing structure disposed in contact with the top surface of said surface acoustic wave actuator, and two positioning portions respectively supported on said sliding bearings; and
a support structure for applying a predetermined force to said positioning portions of said slider subject to a load carried on said slider, keeping the contact pressure between said slider and said surface acoustic wave actuator about a constant value.

2. The load-adjustable surface acoustic wave actuator arrangement as claimed in claim 1, wherein said support structure is disposed at said sliding bearings.

3. The load-adjustable surface acoustic wave actuator arrangement as claimed in claim 1, wherein said support structure is disposed at the positioning portions of said slider.

4. The load-adjustable surface acoustic wave actuator arrangement as claimed in claim 1, wherein said platform comprises a receiving space, which accommodates said slider; said sliding bearings are grooves symmetrically disposed at two sides in said receiving space.

5. The load-adjustable surface acoustic wave actuator arrangement as claimed in claim 4, wherein said support structure comprises a first gas supplier and a second gas supplier, said first gas supplier having an independent gas source and a plurality of gas nozzles arranged in lines at bottom sidewalls of said sliding bearings and controlled to provide an upward gas pressure to the positioning portions of said slider, said second gas supplier having an independent gas source and a plurality of gas nozzles arranged in lines at top sidewalls of said sliding bearings and controlled to provide a downward gas pressure to the positioning portions of said slider.

6. The load-adjustable surface acoustic wave actuator arrangement as claimed in claim 5, wherein said support structure further comprises a third gas supplier, said third gas supplier having an independent gas source and a plurality of gas nozzles arranged in lines at lateral sidewalls of said sliding bearings and controlled to provide a lateral gas pressure to two opposite lateral sides of said slider, keeping movement of said slider along said sliding bearings in direction.

7. The load-adjustable surface acoustic wave actuator arrangement as claimed in claim 4, wherein said support structure comprises a first gas supplier and a second gas supplier, said first gas supplier having an independent gas source and a plurality of gas nozzles arranged in lines at bottom sidewalls of the positioning portions of said slider and controlled to supply a gas to said sliding bearings so as to give an upward pressure to the positioning portions of said slider, said second gas supplier having an independent gas source and a plurality of gas nozzles arranged in lines at top sidewalls of the positioning portions of said slider and controlled to supply a gas to said sliding bearings so as to give a downward pressure to the positioning portions of said slider.

8. The load-adjustable surface acoustic wave actuator arrangement as claimed in claim 7, wherein said support structure further comprises a third gas supplier, said third gas supplier having an independent gas source and a plurality of gas nozzles arranged in lines at lateral sidewalls of the positioning portions of said slider and controlled to respectively supply a gas to said sliding bearings so as to respectively provide a lateral gas pressure to two opposite lateral sides of said slider, keeping movement of said slider along said sliding bearings in direction.

9. The load-adjustable surface acoustic wave actuator arrangement as claimed in claim 4, wherein said support structure comprises a first hydraulic device and a second hydraulic device, said first hydraulic device having a plurality of output nozzles arranged in lines at bottom sidewalls of said sliding bearings and controlled to provide an upward hydraulic fluid pressure to the positioning portions of said slider, said second hydraulic device having a plurality of output nozzles arranged in lines at top sidewalls of said sliding bearings and controlled to provide a downward hydraulic fluid pressure to the positioning portions of said slider.

10. The load-adjustable surface acoustic wave actuator arrangement as claimed in claim 9, wherein said support structure further comprises a third hydraulic device, said third hydraulic device having a plurality of output nozzles arranged in lines at lateral sidewalls of said sliding bearings and controlled to provide a lateral hydraulic fluid pressure to two opposite lateral sides of said slider, keeping movement of said slider along said sliding bearings in direction.

11. The load-adjustable surface acoustic wave actuator arrangement as claimed in claim 4, wherein said support structure comprises a first hydraulic device and a second hydraulic device, said first hydraulic device r having a plurality of output nozzles arranged in lines at bottom sidewalls of the positioning portions of said slider and controlled to supply a hydraulic fluid to said sliding bearings so as to give an upward pressure to the positioning portions of said slider, said second hydraulic device having a plurality of output nozzles arranged in lines at top sidewalls of the positioning portions of said slider and controlled to supply a hydraulic fluid to said sliding bearings so as to give a downward pressure to the positioning portions of said slider.

12. The load-adjustable surface acoustic wave actuator arrangement as claimed in claim 11, wherein said support structure further comprises a third hydraulic device, said third hydraulic device having a plurality of output nozzles arranged in lines at lateral sidewalls of the positioning portions of said slider and controlled to provide a lateral hydraulic fluid pressure to two opposite lateral sides of said slider, keeping movement of said slider along said sliding bearings in direction.

13. The load-adjustable surface acoustic wave actuator arrangement as claimed in claim 4, wherein said support structure comprises a first electromagnetic device and a second electromagnetic device, said first electromagnetic device being arranged at bottom sidewalls of said sliding bearings and corresponding sides of the positioning portions of said slider controlled to provide an upward magnetic force to the positioning portions of said slider, said second electromagnetic device being arranged at top sidewalls of said sliding bearings and corresponding sides of the positioning portions of said slider and controlled to provide a downward magnetic force to the positioning portions of said slider.

14. The load-adjustable surface acoustic wave actuator arrangement as claimed in claim 13, wherein said support structure further comprises a third electromagnetic device arranged at lateral sidewalls of said sliding bearings and corresponding sides of the positioning portions of said slider and controlled to provide a lateral magnetic force to two opposite lateral sides of said slider, keeping movement of said slider along said sliding bearings in direction.

15. The load-adjustable surface acoustic wave actuator arrangement as claimed in claim 1, wherein said slider comprises a slider body suspended inside said platform; said positioning portions of said slider are respectively horizontally extended from two opposite lateral sides of said slider body and supported on said sliding bearings and respectively spaced from lateral sidewalls of said sliding bearings at a distance for receiving the predetermined force from said support structure.

16. The load-adjustable surface acoustic wave actuator arrangement as claimed in claim 1, wherein said slider comprises a pressure sensor for detecting the pressure of load carried on said slider and to transmit detected pressure signal to a processor for enabling said processor to control the operation of said support structure.
